(19) United States
(12) Patent Application Publication
(10) Pub. No.: US 2025/0218808 A1
(43) Pub. Date: Jul. 3, 2025

(54) SUBSTRATE TREATING APPARATUS

(71) Applicant: SEMES CO., LTD., Cheonan-si (KR)

(72) Inventors: Eun Seok KIM, Cheonan-si (KR); Seung Hoon OH, Cheonan-si (KR); Jin Se PARK, Cheonan-si (KR)

(73) Assignee: SEMES CO., LTD., Cheonan-si (KR)

(21) Appl. No.: 19/004,721

(22) Filed: Dec. 30, 2024

(30) Foreign Application Priority Data
Dec. 29, 2023 (KR) 10-2023-0197548

(51) Int. Cl. H01L 21/67; F26B 5/00

(52) U.S. Cl. CPC H01L 21/67034; F26B 5/005

(57) ABSTRACT

The present invention provides a substrate treating apparatus. The substrate treating apparatus includes: a vessel providing a sealable treatment space; and a substrate supporting member positioned in the treatment space of the vessel and supporting a substrate, wherein the vessel includes: a through-hole formed through from an outer surface to an inner surface such that a process fluid is supplied to the treatment space; and a pipe connection assembly provided on an outer surface on which the through-hole is formed, and provided for connection with a process fluid supply pipe.

### CROSS-REFERENCE TO RELATED APPLICATIONS

This application claims priority to and the benefit of Korean Patent Application No. 10-2023-0197548 filed in the Korean Intellectual Property Office on Dec. 29, 2023, the entire contents of which are incorporated herein by reference.

### TECHNICAL FIELD

The present invention relates to a substrate treating apparatus.

### BACKGROUND ART

In order to manufacture a semiconductor device, a desired pattern is formed on a substrate such as a wafer through various processes such as photographing, etching, ashing, ion injection, and thin film deposition. Various treatment liquids and treatment gases are used in each of the processes, and particles and process byproducts are produced during the processes. A cleaning process is performed before and after the processes to remove particles and process byproducts from a substrate.

A general cleaning process treats a substrate with a chemical and a rinse solution and then performs a drying process. As an example of the drying process, there is a rotary drying process that removes a rinse solution remaining on a substrate by rotating the substrate at a high speed. However, such a rotary drying method poses concerns about potential collapse of the pattern formed on a substrate.

Accordingly, recently, a supercritical drying process that replaces a rinse solution remaining on a substrate with an organic solvent having low surface tension by supplying the organic solvent such as isopropyl alcohol (IPA) to the substrate and then removes the organic solvent remaining on the substrate by supplying a treatment liquid in a supercritical state to the substrate is used. In the supercritical drying process, a drying gas is supplied to a sealed process chamber and is heated and pressurized. Accordingly, the temperature and process of the drying gas both increase over critical points and the state of the drying gas changes into a supercritical state.

A substrate treating apparatus that performs a supercritical drying process has an internal space formed by combining an upper body and a lower body and dries a substrate by supplying a drying gas after maintaining the pressure of the internal space at a high level with the substrate such as a wafer supported by a supporting member in the internal space.

In the substrate treating apparatus that performs a supercritical drying process, a supercritical fluid supply pipe is inserted in a chamber body and then fixed by welding. However, according to this structure, a portion of a gap between a pipe and a hole is bonded (welded), so the discontinuous surface of the material acts as a stress concentration factor and causes reduction of the durability of the chamber body.

### SUMMARY OF THE INVENTION

An object of the present invention is to provide a substrate treating apparatus that can improve durability by removing stress concentration factors.

An object of the present invention is to provide a substrate treating apparatus that can additionally protect the welds between a pressure vessel and a pipe.

The objects of the present invention are not limited thereto and other objectives not stated herein may be clearly understood by those skilled in the art from the following description.

An exemplary embodiment of the present invention, a substrate treating apparatus comprising: a vessel providing a sealable treatment space; and a substrate supporting member positioned in the treatment space of the vessel and supporting a substrate, wherein the vessel comprises: a through-hole formed through from an outer surface to an inner surface such that a process fluid is supplied to the treatment space; and a pipe connection assembly provided on an outer surface on which the through-hole may formed, and provided for connection with a process fluid supply pipe.

According to an embodiment of the present invention, the pipe connection assembly may comprises; a protruding port through which the through-hole extends and that protrudes from the outer surface; and a connection pipe connected to the protruding port by welding and having a joint for fitting with the process fluid supply pipe.

According to an embodiment of the present invention, the pipe connection assembly may comprises; a protective cap provided to surround a weld between the protruding port and the expansion pipe and a weld between the expansion pipe and the connection pipe.

According to an embodiment of the present invention, the protective cap may be provided to surround the joint.

According to an embodiment of the present invention, the expansion pipe has a first end portion having a first inner diameter the same as an inner diameter of the protruding port, a second end portion having a second inner diameter the same as an inner diameter of the connection pipe, and a connecting portion connecting the first end portion and the second end portion; the inner diameter of the protruding port is the same as an inner diameter of the through-hole; and the inner diameter of the connecting pipe may be the same as an inner diameter of the process fluid supply pipe.

According to an embodiment of the present invention, the through-hole may has roughness the same as surface roughness of an inner surface of the process fluid supply pipe.

According to an embodiment of the present invention, the through-hole may be electro-polished.

According to an embodiment of the present invention, the through-hole may has an inner diameter larger than the inner diameter of the process fluid supply pipe.

According to an embodiment of the present invention, the process fluid may be a supercritical fluid.

An exemplary embodiment of the present invention, a substrate treating apparatus comprising: a vessel providing a sealable treatment space through a combination of an upper body and a lower body; and a substrate supporting member positioned in the treatment space of the vessel and supporting a substrate, wherein the upper body comprises a first through-hole formed through from an inner lower surface in contact with the treatment space to an outer upper surface, and a first pipe connection assembly provided on the outer upper surface for connection of the first through-hole and a first process fluid supply pipe; and the lower body may comprises a second through-hole formed through from an inner top surface being in contact with the treatment space to an outer lower surface, and a second pipe connection assembly provided on the outer lower surface for connection of the second through-hole and a second process fluid supply pipe.

According to an embodiment of the present invention, the first pipe connection assembly comprises: a first protruding port through which the first through-hole extends and that protrudes from the outer upper surface; and a first connection pipe connected to the first protruding port by welding and having a joint for fitting with the first process fluid supply pipe, and the second pipe connection assembly may comprises: a second protruding port through which the second through-hole extends and that protrudes from the outer lower surface; and a second connection pipe connected to the second protruding port by welding and having a joint for fitting with the second process fluid supply pipe.

According to an embodiment of the present invention, a first protective cap provided to surround a weld between the first protruding port and the first expansion pipe and a weld between the first expansion pipe and the first connection pipe, and the second pipe connection assembly further may comprises: a second protective cap provided to surround a weld between the second protruding port and the second expansion pipe and a weld between the second expansion pipe and the second connection pipe.

According to an embodiment of the present invention, the first and second protective caps may be provided to surround the joint.

According to an embodiment of the present invention, the first expansion pipe and the second expansion pipe have a first end portion having a first inner diameter the same as inner diameters of the first and second protruding ports, a second end portion having a second inner diameter the same as inner diameters of the first and second connection pipes, and a connecting portion connecting the first end portion and the second end portion; the inner diameters of the first and second protruding ports are the same as inner diameters of the first and second through-holes; the inner diameters of the first and second connection pipes are the same as inner diameters of the first and second process fluid supply pipes; and the first and second through-holes may have an inner diameter larger than the inner diameters of the first and second process fluid supply pipes.

According to an embodiment of the present invention, the first and second through-holes may have roughness the same as surface roughness of inner surfaces of the first and second process fluid supply pipes.

According to an embodiment of the present invention, the first and second through-holes may be electro-polished.

According to an embodiment of the present invention, the process fluid may be a supercritical fluid.

An exemplary embodiment of the present invention, a substrate treating apparatus comprising: a vessel providing a sealable treatment space through a combination of an upper body and a lower body; and a substrate supporting member positioned in the treatment space of the vessel and supporting a substrate, wherein the upper body and the lower body each comprise: a through-hole formed through from an outer surface to an inner surface such that a process fluid is supplied to the treatment space; and a pipe connection assembly provided on an outer surface on which the through-hole is formed, and provided for connection with a process fluid supply pipe, and the pipe connection assembly comprises: a protruding port through which the through-hole extends and that protrudes from the outer surface; an expansion pipe connected to the protruding port by welding; and a connection pipe connected to the expansion pipe by welding and having a joint for fitting with the process fluid supply pipe.

According to an embodiment of the present invention, the pipe connection assembly further comprises a protective cap may be provided to surround a weld between the protruding port and the expansion pipe and a weld between the expansion pipe and the connection pipe.

According to an embodiment of the present invention, the expansion pipe has a first end portion having a first inner diameter the same as an inner diameter of the protruding port, a second end portion having a second inner diameter the same as an inner diameter of the connection pipe, and a connecting portion connecting the first end portion and the second end portion; the inner diameter of the protruding port is the same as an inner diameter of the through-hole; the inner diameter of the connection pipe is the same as an inner diameter of the process fluid supply pipe; the first and second through-holes have an inner diameter larger than inner diameters of the first and second process fluid supply pipes; and the through-hole may has roughness the same as surface roughness of an inner surface of the process fluid supply pipe.

According to an embodiment of the present invention, it is possible to improve durability by removing stress concentration factors at pipe connection assemblies.

According to an embodiment of the present invention, it is possible to additionally protect the weld between a chamber and a pipe.

Effects of the present invention are not limited to those described above and effects not stated above will be clearly understood to those skilled in the art from the specification and the accompanying drawings.

### BRIEF DESCRIPTION OF THE DRAWINGS

FIG. 1 is a view showing a substrate treating apparatus according to an embodiment of the present invention.

FIG. 2 is a view schematically showing an embodiment of the liquid treatment chamber of FIG. 3.

FIG. 3 is a view schematically showing an embodiment of the drying chamber of FIG. 1.

FIG. 4 is a view showing that the upper body and the lower body of FIG. 3 are positioned at a closed position.

FIG. 5 is a view showing that the first clamping body and the second clamping body of FIG. 3 are positioned at a clamping position.

FIG. 6 is an enlarged view illustrating the first pipe connection assembly shown in FIG. 3.

FIG. 7 is an enlarged view illustrating a first pipe connection assembly according to a modified embodiment.

FIG. 8 is an exploded perspective view of the first pipe connection assembly shown in FIG. 7.

FIG. 9 is a view showing another example of a first protective cap.

FIG. 10 is a view showing another example of a first expansion pipe of the first pipe connection assembly shown in FIG. 7.

FIG. 11 is a view showing a modified example of a first protruding port.

FIG. 12 is a view schematically showing another example of a drying chamber.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

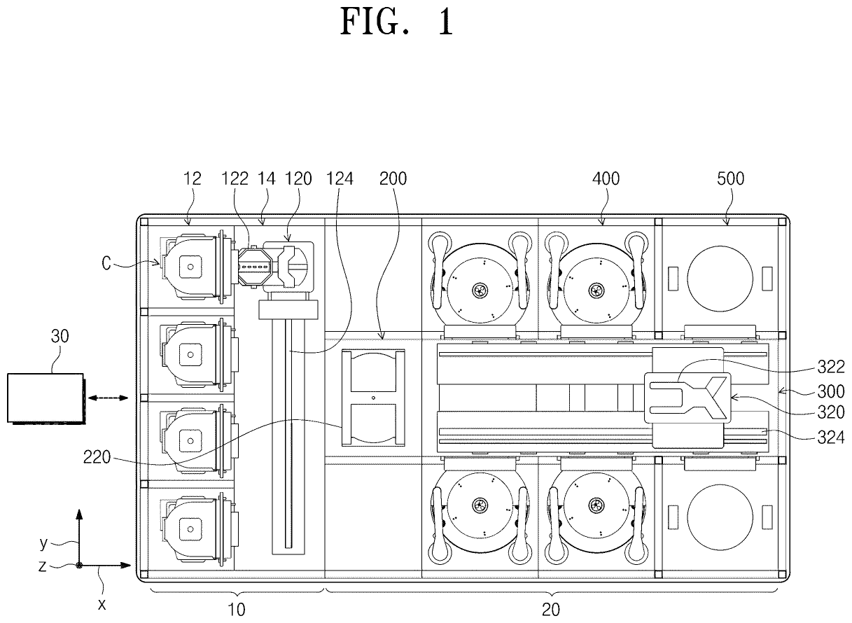

Hereafter, embodiments of the present invention are described with reference to FIG. 1 to FIG. 15.

FIG. 1 is a view showing a substrate treating apparatus according to an embodiment of the present invention.

Referring to FIG. 1, a substrate treating apparatus includes an index module 10, a treatment module 20, and a control unit 30. When seen from above, the index module 10 and the treatment module 20 are disposed in one direction. Hereafter, the direction in which the index module 10 and the treatment module 20 are arranged is referred to as a first direction X, a direction perpendicular to the first direction X when seen from above is referred to as a second direction Y, and a direction perpendicular to both of the first direction X and the second direction Y is referred to as a third direction Z.

The index module 10 transfers substrates W to the treatment module 20 from containers C accommodating the substrates W and puts the substrates W processed at the processing module 20 into the containers C. The longitudinal direction of the index module 10 is provided in the second direction Y. The index module 10 has a loadport 12 and an index frame 14. The loadport 12 is positioned at the opposite side to the treatment module 20 with the index frame 14 therebetween. The containers C accommodating substrates W are placed in the loadport 12. The loadport 12 may be provided in multiple instances and the plurality of loadports 12 may be disposed in the second direction Y.

The container C may be a container for sealing such as a Front Open Unified Pod (FOUP). The container C may be placed in the loadport 12 by a worker or a conveying device (not shown) such as an overhead transfer, an overhead conveyor, or an automatic guided vehicle.

An index robot 120 is provided at the index frame 14. A guide rail 124 of which the longitudinal direction is provided in the second direction Y is provided in the index frame 14 and the index robot 120 may be provided to be movable on the guide rail 124. The index robot 120 includes a hand 122 on which substrates W are placed and the hand 122 may be provided to be able to move forward and backward, rotate about the third direction Z, and move in the third direction Z. The hand 122 may be provided in multiple instances to be spaced apart from each other in the up-down direction and the hands 122 can move forward and backward independently from each other.

The control unit 30 can control the substrate treating apparatus. The control unit 30 may include: a process controller that is a microprocessor (computer) that performs control of the substrate treating apparatus; a user interface that is a keyboard through which an operator performs command input operation, etc. to manage the substrate treating apparatus, a display that visualizes and displays the operation situation of the substrate treating apparatus, etc.; and a memory that stores a control program for performing treatment, which is performed in the substrate treating apparatus, under control of the process controller, a program for performing treatment on each component in accordance with various data and treatment conditions, that is, a treatment recipe. Further, the user interface and the memory may be connected to the process controller. The treatment recipe may be stored in a memory medium of the memory and the memory medium may be a hard disk and may be a portable disc such as a CD-ROM and a DVD, and a semiconductor memory such as a flash memory.

The treatment module 20 includes a buffer unit 200, a transfer chamber 300, a liquid treatment chamber 400, and a drying chamber 500. The buffer unit 200 provides a space in which substrates W that are loaded into the treatment module 20 and substrates W that are unloaded from the treatment module 20 temporarily stay. The liquid treatment chamber 400 performs a liquid treatment process of performing liquid treatment on substrates W by supplying liquid onto the substrates W. The drying chamber 500 can perform a drying process that removes liquid remaining on substrates W. The transfer chamber 300 transfers substrates W between the buffer unit 200, the liquid treatment chamber 400, and the drying chamber 500.

The longitudinal direction of the transfer chamber 300 may be provided in the first direction X. The buffer unit 200 may be disposed between the index module 10 and the transfer chamber 300. The liquid treatment chamber 400 and the drying chamber 500 may be disposed on sides of the transfer frame 300. The liquid treatment chamber 400 and the transfer chamber 300 may be disposed in the second direction Y. The drying chamber 500 and the transfer chamber 300 may be disposed in the second direction Y. The buffer unit 200 may be positioned at an end of the transfer chamber 300.

According to an embodiment, the liquid treatment chambers 400 are disposed at both sides of the transfer chamber 300, the drying chambers 500 are disposed at both sides of the transfer chamber 300, and the liquid treatment chambers 400 may be disposed at positions close to the buffer unit 200 in comparison to the drying chambers 500. The liquid treatment chambers 400 may be provided in an array of A×B (A and B are each a natural number of 1 or more) in the first direction X and the third direction Z, respectively, at a side of the transfer chamber 300. Further, the drying chambers 500 may be provided by the number of C×D (C and D are each a natural number of 1 or more) in the first direction X and the third direction Z, respectively, at a side of the transfer chamber 300. Unlike the above description, only the liquid treatment chambers 400 may be provided at a side of the transfer chamber 300 and only the drying chambers 500 may be provided at another side.

The transfer chamber 300 has a transfer robot 320. A guide rail 324 of which the longitudinal direction is provided in the first direction X is provided in the transfer chamber 300 and the transfer robot 320 may be provided to be movable on the guide rail 324. The transfer robot 320 includes a hand 322 on which substrates W are placed and the hand 322 may be provided to be able to move forward and backward, rotate about the third direction Z, and move in the third direction Z. The hand 322 may be provided in multiple instances to be spaced apart from each other in the up-down direction and the hands 322 can move forward and backward independently from each other.

The buffer unit 200 has a plurality of buffers 220 on which substrates W are placed. The buffers 220 may be disposed to be spaced apart from each other in the third direction Z. The buffer unit 200 is open on the front face and the rear face. The front face is a surface that faces the index module 10 and the rear face is a surface that faces the transfer chamber 300. The index robot 120 can approach the buffer unit 200 through the front face and the transfer robot 320 can approach the buffer unit 200 through the rear face.

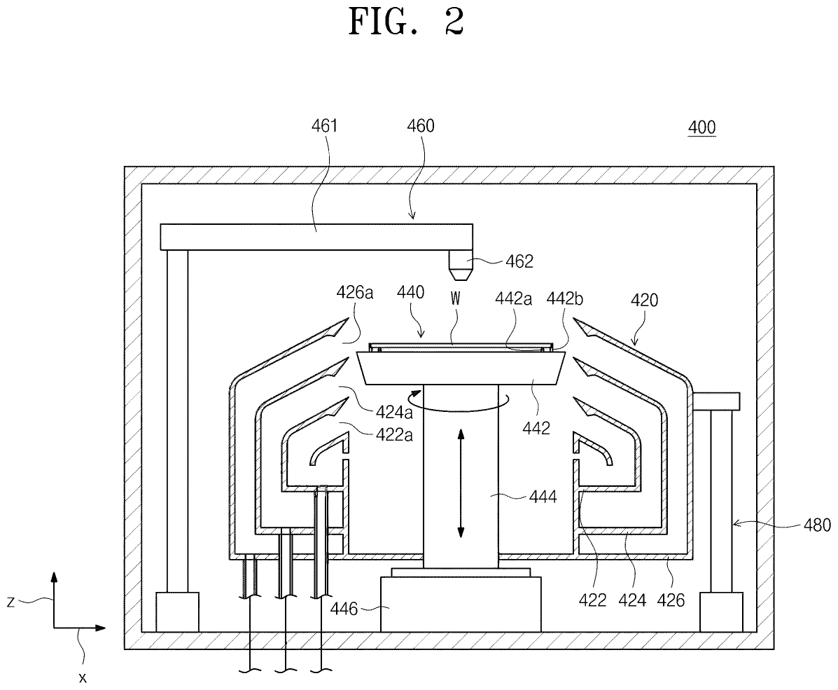

FIG. 2 is a view schematically showing an embodiment of the liquid treatment chamber of FIG. 1.

Referring to FIG. 2, the liquid treatment chamber 400 includes a housing 410, a cup 420, a supporting unit 440, a liquid supply unit 460, and an elevation unit 480.

The housing 410 may have an internal space in which substrates W are treated. The housing 410 may have a hexahedral shape. For example, the housing 410 may have a rectangular prism shape. Further, an opening (not shown) through which substrates W are loaded or unloaded may be formed on the housing 410. Further, a door (not shown) selectively opening and closing the opening may be installed on the housing 410.

The cup 420 may have a box shape with an open top. The cup 420 may have a treatment space and substrates W can be liquid-treated in the treatment space. The supporting unit 440 supports substrates W in the treatment space. The liquid supply unit 460 supplies a treatment liquid to a substrate W supported on the supporting unit 440. A plurality of kinds of treatment liquids is provided and may be sequentially supplied to a substrate W. The elevation unit 480 adjusts the relative height between the cup 420 and the supporting unit 440.

According to an example, the cup 420 has a plurality of recovery baths 422, 424, and 426. The recovery baths 422, 424, and 426 each have a recovery space for recovering liquid used to treat a substrate. The recovery baths 422, 424, and 426 are each provided in a ring shape surrounding the supporting unit 440. The treatment liquids splashed by rotation of a substrate W when the liquid treatment process is performed flow into the recovery spaces through inlets 422a, 424a, and 426a of the recovery baths 422, 424, and 426, respectively. According to an example, the cup 420 has a first recovery bath 422, a second recovery bath 424, and a third recovery bath 426. The first recovery bath 422 is disposed to surround the supporting unit 440, the second recovery bath 424 is disposed to surround the first recovery bath 422, and the third recovery bath 426 is disposed to surround the second recovery bath 424. The second inlet 424a for supplying liquid into the second recovery bath 424 may be positioned higher than the first inlet 422a for supplying liquid into the first recovery bath 422, and the third inlet 426a for supplying liquid into the third recovery bath 426 may be positioned higher than the second inlet 424a.

The supporting unit 440 has a supporting plate 442 and an actuating shaft 444. The upper surface of the supporting plate 442 is provided substantially in a circular shape and may have a diameter larger than substrates W. Supporting pins 442a supporting the rear surface of a substrate W is provided at the center portion of the supporting plate 442 and are provided such that the upper ends thereof protrude from the supporting plate 442 to space a substrate W a predetermined distance from the supporting plate 442. Chuck pins 442b are provided on the edge portion of the supporting plate 442. The chuck pins 442b protrude upward from the supporting plate 442 and support the side of a substrate W to prevent the substrate W from separating from the supporting unit 440 when the substrate W is rotated. The actuating shaft 444 is driven by an actuator 446, is connected to the center of the underside of a substrate W, and rotates the supporting plate 442 about the center axis thereof.

According to an embodiment, the liquid supply unit 460 may include a nozzle 462. The nozzle 462 can supply a treatment liquid to a substrate W. The treatment liquid may be a chemical, a rinse solution, or an organic solvent. The chemical may be a chemical that has the property of strong acid or strong base. Further, the rinse solution may be deionized water. Further, the organic solvent may be isopropyl alcohol (IPA). Further, the liquid supply unit 460 may include a plurality of nozzles 462 and the nozzles 462 can discharge different kinds of treatment liquid. For example, any one of the nozzles 462 may discharge a chemical, another one of the nozzles 462 may discharge a rinse solution, and another one of the nozzles 462 may discharge an organic solvent. Further, the control unit 30 can control the liquid supply unit 460 to supply a rinse solution to a substrate W from another one of the nozzles 462 and then supply an organic solvent from another one of the nozzles 462. Accordingly, the rinse solution supplied on the substrate W can be replaced with the organic solvent with low surface tension.

The elevation unit 480 moves the cup 420 in the up-down direction. The relative height between the cup 420 and a substrate W is changed by up-down movement of the cup 420. Accordingly, the recovery baths 422, 424, and 426 that recover treatment liquids are changed, depending on the kinds of treatment liquids that are supplied to substrates W, so it is possible to separately recover treatment liquids. Unlike the above description, the cup 420 may be fixed and the elevation unit 480 may move the supporting unit 440 in the up-down direction.

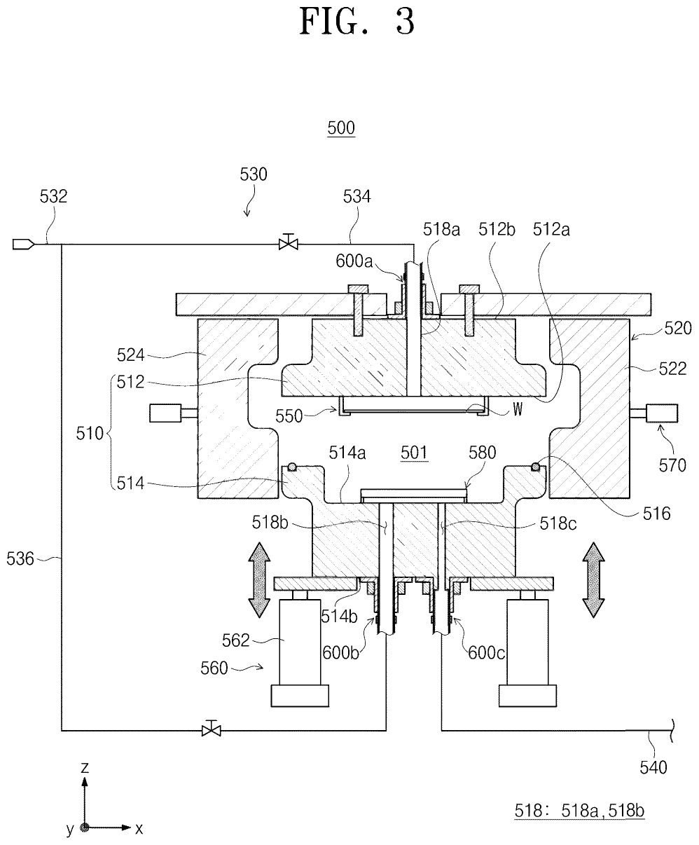

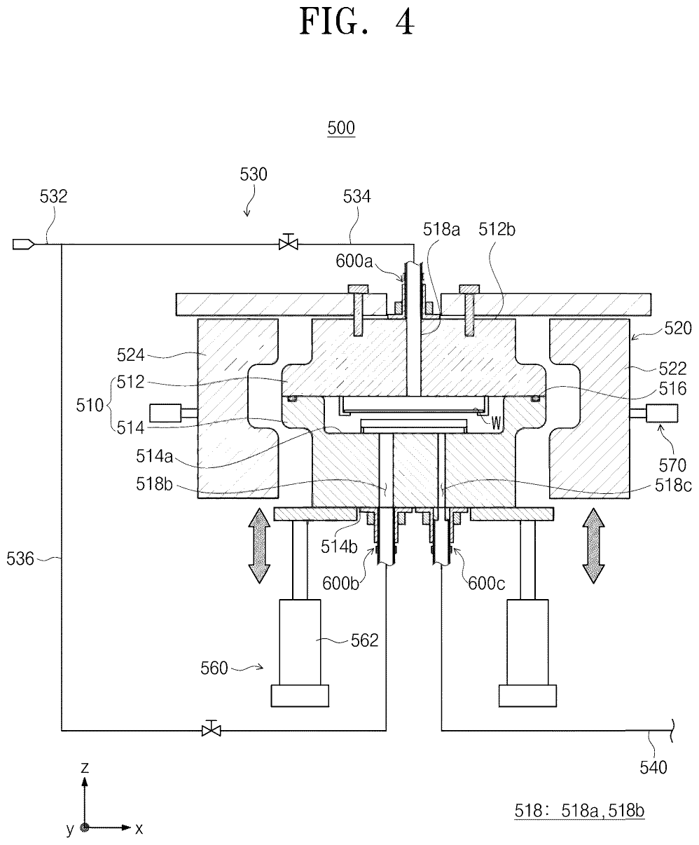

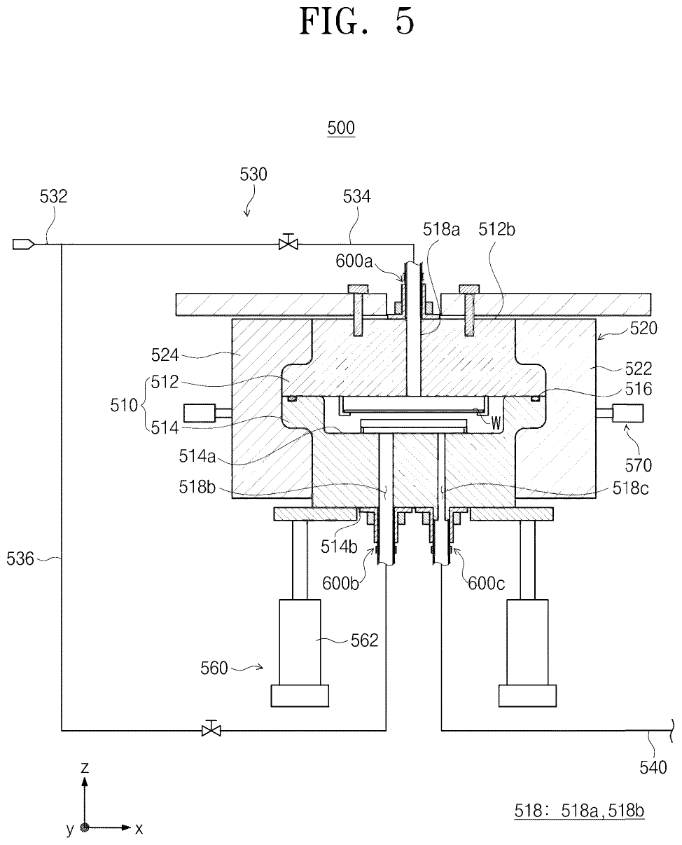

FIG. 3 is a view schematically showing an embodiment of the drying chamber of FIG. 1, FIG. 4 is a view showing that the upper body and the lower body of FIG. 3 are positioned at a closed position, and FIG. 5 is a view showing that the first clamping body and the second clamping body of FIG. 3 are positioned at a clamping position.

Referring to FIG. 3 to FIG. 5, a drying chamber 500 according to an embodiment of the present invention can remove a treatment liquid remaining on a substrate W using a drying fluid in a supercritical state. For example, the drying chamber 500 can perform a drying process of removing an organic solvent remaining on a substrate W using carbon dioxide (CO₂) in a supercritical state. For example, a supercritical process may include a cleaning process a drying process, an etching process, etc. that uses a supercritical fluid. The supercritical fluid may be a substance having diffusivity, viscosity, and surface tension similar to those of gas, having solubility similar to that of liquid, and having temperature and pressure over critical points. For example, the supercritical fluid may include carbon dioxide (CO₂), water (H₂O), methane (CH₄), ethane (C₂H₆), propane (C₃H₈), ethylene (C₂H₄), propylene (C₃H₆), methanol (CH₃OH), ethanol (C₂H₅OH), sulfur hexafluoride (SF₆), acetone (C₃H₆O), etc.

The drying chamber 500 may include a chamber body 510, a clamping body 520, a fluid supply unit 530, a fluid exhaust line 540, a supporting member 550, a first moving unit 560, a second moving unit 570, and a filler member 600. The chamber body 510 and the clamping body 520 may be collectively referred to as a body.

The chamber body 510 has a vessel shape including an upper body 512 and a lower body 514. The upper body 512 and the lower body 514 provide a treatment space 501 by combining with each other. The treatment space 501 may include an upper space 502 corresponding to the upper portion and a lower space 503 corresponding to a lower portion with respect to a substrate placed on the supporting member. The upper body 512 may include a lower surface 513. The lower surface 513 of the upper body 512 may be provided as an upper wall of the chamber body 510. The lower body 514 may include an upper surface 515. The upper surface 515 of the lower body 514 may be provided as a lower wall of the chamber body 110.

Any one of the upper body 512 and the lower body 514 may be configured to be movable with respect to the other one. For example, any one of the upper body 512 and the lower body 514 can be moved by the first moving unit 560. The first moving unit 560 may include an elevation actuator 562 and an elevation plate 564. The actuator 562 is provided in multiple instances and can be connected to the elevation plate 564. The elevation plate 564 can be coupled to the lower body 514. When the elevation actuators 562 moves up and down the elevation plate 564, the lower body 514 can also be moved up and down with the elevation plate 564. A heater for heating a drying fluid supplied to the treatment space 501 may be embedded in the chamber body 510. Further, a groove may be formed at the lower body 514 and an O-ring 516 that is a sealing member may be inserted in the groove to increase hermeticity of the internal space 501 when the upper body 512 and the lower body 514 are at a closed position.

The fixed of the upper body 512 is fixed and the lower body 514 can be moved up and down in the third direction Z by the first moving unit 560. Hereafter, the position where the lower body 514 forms the treatment space 501 in contact with the upper body 512 by moving up is referred to as a closed position and the position where the lower body 514 is separate from the upper body 512 by moving down is referred to as an open position.

The clamping body 520 may include a first clamping body 522 and a second clamping body 524. The first clamping body 522 and the second clamping body 524 can clamp the chamber body 510 at opposite positions to each other. The inner sides of the first clamping body 522 and the second clamping body 524 may have a shape substantially corresponding to the outer side of the chamber body 510 at the closed position. The first clamping body 522 and the second clamping body 524 can be moved by the second moving unit 570. The second moving unit 570 may be provided in multiple instances.

The supporting member 550 can support a substrate W in the treatment space 501. The supporting unit 550 can support the edge area of a substrate W in the treatment space 501. The supporting member 550 can support the bottom surface of the edge area of a substrate W. The supporting member 550 may be installed at the upper body 512.

A supply hole 518 can supply a supercritical fluid into the chamber body 510. The supply hole 518 may include a first through-hole 518a and a second through-hole 518b.

The second through-hole 518b may be provided in the center area of the lower wall of the lower body 514. In an embodiment, the second through-hole 518b may be provided at a predetermined position from the center of the lower wall. In an embodiment, the center of the lower wall may be a position corresponding to the center of a substrate W on a vertical line when the substrate W is supported on the supporting member 550. The second through-hole 518b supplies a supercritical fluid to the lower space 503 positioned under a substrate W in the treatment space 501. The second through-hole 518b is formed through the lower body 514 from an inner top surface 514a being in contact with the treatment space 501 to an outer lower surface 514b.

The first through-hole 518a is provided in the center area of the upper wall of the upper body 512. The first through-hole 518a supplies a supercritical fluid to the upper space 502 positioned over a substrate W in the treatment space 501. The supercritical fluid supplied from the first through-hole 518a can be provided to the top surface of a substrate W. The first through-hole 518a is formed through the upper body 512 from an inner underside 512a being in contact with the treatment space to an outer upper surface 512b. The first through-hole 518a has an inner diameter the same as the inner diameter of an upper branch line 534 that is a process fluid supply pipe. The second through-hole 518b has an inner diameter the same as the inner diameter of a lower branch line 536 that is a process fluid supply pipe.

An exhaust hole 518c exhausts fluid staying in the chamber body 510 to the outside. The exhaust hole 518c is provided in the lower wall of the lower body 514. The exhaust hole 518c may be positioned adjacent to a second support port 518b. The exhaust hole 518c may be provided in the center area of the lower wall of the lower body. The diameter of the exhaust hole 518c may be the same as the diameter of the second supply port 518b. The fluid exhausted from the exhaust hole 518c may include a supercritical fluid containing an organic solvent dissolved therein. The fluid exhausted from the exhaust hole 518c may be sent to a recycling apparatus (not shown). The fluid can be separated into a supercritical fluid and the organic solvent in the recycling apparatus. Unlike, the fluid exhausted from the exhaust hole 518c may be discharged to the atmosphere through a fluid exhaust line 540.

The fluid supply unit 530 supplies a process fluid into the treatment space 501 of the chamber body 510. According to an embodiment, the process fluid can be supplied into the treatment space 501 in a supercritical state. Unlike, the process fluid may be supplied into the treatment space 501 in a gas state and the phase thereof may be changed into a supercritical state in the treatment space 501. According to an example, the fluid supply unit 530 has a main supply line 532, an upper branch line 534, and a lower branch line 536. The upper branch line 534 and the lower branch line 536 diverge from the main supply line 532.

The upper branch line 534 is connected to the first through-hole 518a through a first pipe connection assembly 600a. The lower branch line 536 is connected to the second through-hole 518b through a second pipe connection assembly 600b. The fluid exhaust line 540 is connected to the exhaust hole 518c through a third pipe connection assembly 600c. The supercritical fluid in the treatment space 501 of the chamber body 510 is exhausted to the outside through the fluid exhaust line 540. The fluid exhaust line 540 may be connected to a depressing member (not shown) providing decompression to the treatment space. The decompressing member may be a pump. However, the decompressing member is not limited thereto and may be variously modified into well-known devices that can provide decompression to the treatment space.

The filler member 580 is positioned under the supporting unit 540. The filler member 580 has a plate shape. The filler member 580 can stop direct spray of the supercritical fluid supplied from the second through-hole 518b to the rear surface of a substrate W. Further, the volume of the treatment space 501 can be reduced by the filler member 580. Further, the filler member 580 can increase the turbulence intensity of a treatment fluid by inducing a collision of the treatment fluid that is supplied into the treatment space. Accordingly, the filler member 580 can decrease the amount of the supercritical fluid that is used for the drying process and can decrease the process time while maintaining the process performance.

Meanwhile, the first pipe connection assembly 600a to the third pipe connection assembly 600c each include a protruding port 610, a connection pipe 630, and a protective gap 640, and the first pipe connection assembly 600a is described in detail below. The second pipe connection assembly 600b and the third pipe connection assembly 600c have the same configuration as the first pipe connection assembly 600a, so they are not described in detail.

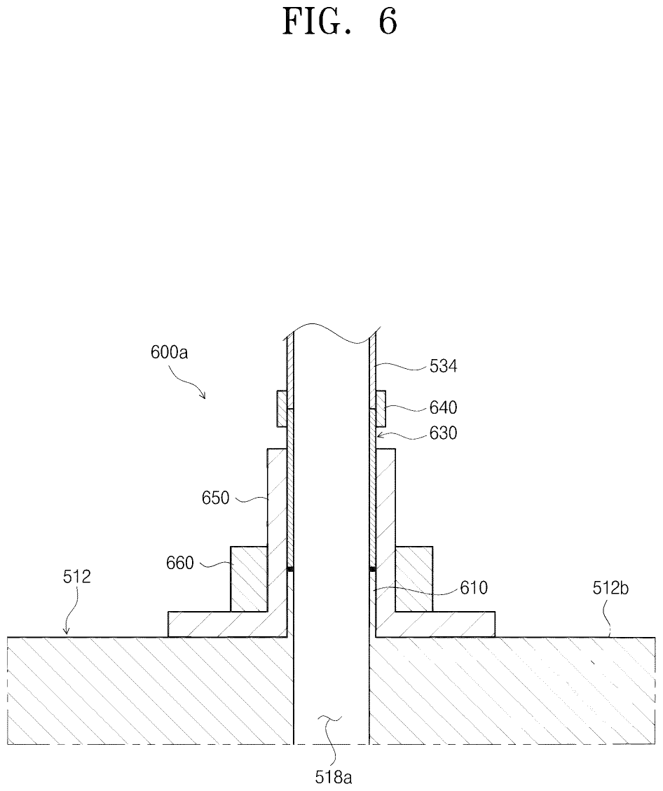

FIG. 6 is an enlarged view illustrating the first pipe connection assembly shown in FIG. 3.

Referring to FIG. 6, the first pipe connection assembly 600a is provided on the outer upper surface of the upper body 512. The first pipe connection assembly 600a may include a first protruding port 610, a first connection pipe 630, and a first protective cap 650.

The first protruding port 610 protrudes from the outer upper surface 512b of the upper body 512. The first protruding port 610 is provided integrally with the upper body 512.

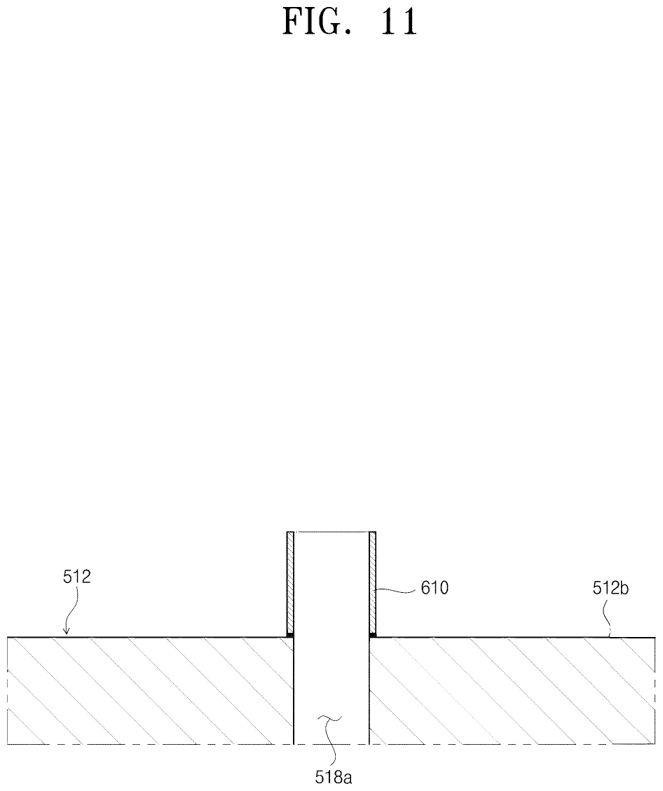

FIG. 11 is a view showing a modified example of the first protruding port. As shown in FIG. 11, the first protruding port 610 may be separately manufactured and then fixed to the outer upper surface 512b of the upper body 512 by welding.

Referring to FIG. 6 again, the first through-hole 518a extends through the first protruding port 610. The first connection pipe 630 can be connected to the first protruding port 610 by welding. As an example, the first connection pipe 630 and the first protruding port 610 may be welded by butt welding.

The first connection pipe 630 has a joint 640 at the upper end for fitting with the upper branch line 534. Though not shown in detail, the joint may have a well-known structure. The first connection pipe 630 and the first through-hole 518a has an inner diameter the same as the inner diameter of the upper branch line 534.

The first protective cap 650 may be provided to surround the weld between the first protruding port 610 and the first connection pipe 630. The first protective cap 650 may be composed of two bodies for easy assembly. The first protective cap 650 can be fixed by a separate clamp 660. The clamp 660 can be implemented in various ways. Though not shown, the first protective cap 650 may be bolted to the upper body 512.

Meanwhile, it is preferable that the first through-hole 518a has the same surface roughness as that of the inner surface of the upper branch line 534. Since the first through-hole 518a has the same surface roughness as that of the inner surface of the upper branch line 534, it is possible to prevent a pressure drop loss and turbulence generation and minimize contamination in the treatment space.

To this end, the first through-hole 518a can be surface-treated to the level of the surface roughness of the inner surface of the upper branch line 534. The first through-hole 518a can be primarily machined through buffing, grinding, polishing, burnishing, reaming, or the like and then surface-treated by electro-polishing (EP). To perform electro-polishing on the first through-hole 518a, an electrode rod (not shown) smaller than the diameter of the first through-hole 518a is manufactured, a negative voltage is applied to the electrode rod, and a positive voltage is applied to the upper body 512, whereby surface treatment is performed. That is, an electrode rod is inserted into the first through-hole 518a of the upper body 512 which is formed through machining, an electrolyte is supplied between the first through-hole 518a of the upper body 512 and the electrode rod, a negative voltage is applied to the electrode rod, and a positive voltage is applied to the upper body 512, whereby the first through-hole 518a can be surface-treated.

According to the substrate treating apparatus having the configuration described above, it is possible to remove a discontinuous surface of a stress concentration factor material by changing the welding position of a supply line from a position with high force and deformation to a position with less force and deformation.

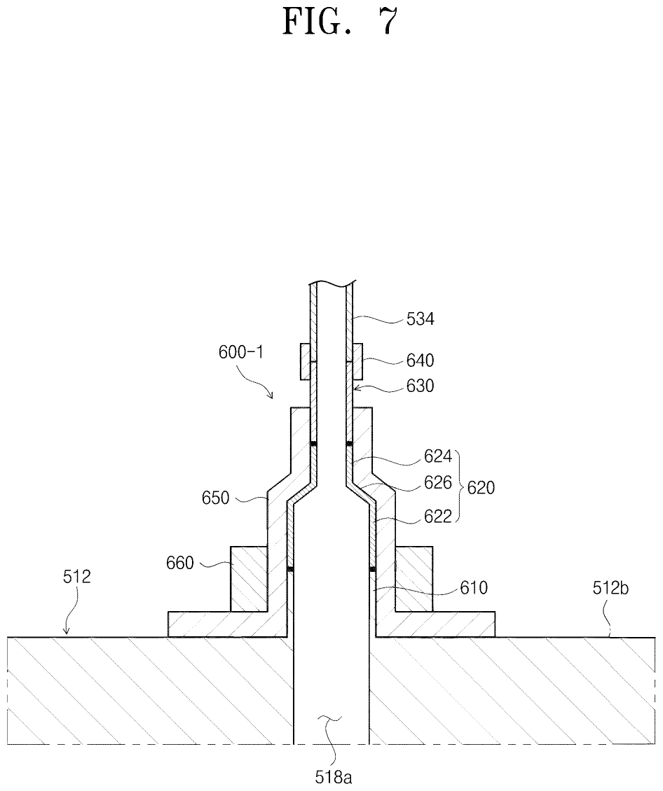

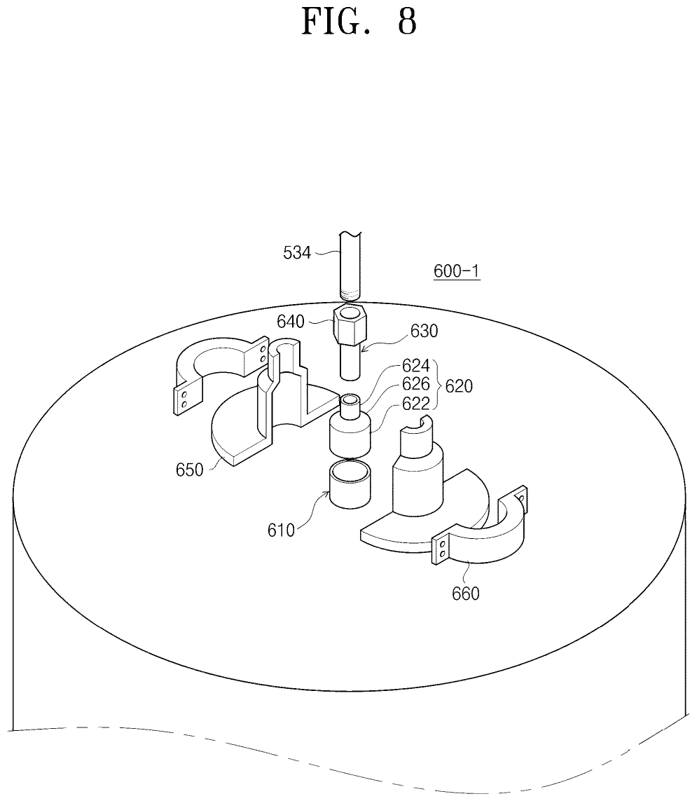

FIG. 7 is an enlarged view illustrating a first pipe connection assembly according to a modified embodiment and FIG. 8 is an exploded perspective view of the first pipe connection assembly shown in FIG. 7.

Referring to FIG. 7 and FIG. 8, a first pipe connection assembly 600-1 according to a first modified embodiment is provided on the outer sop surface of the upper body. The first pipe connection assembly 600-1 includes a first protruding port 610, a first expansion pipe 620, a first connection pipe 630, and a first protective cap 650, and these are substantially similar in configuration and function to the first protruding port 610, the first expansion pipe 620, the first connection pipe 630, and the first protective cap 650 shown in FIG. 6, so the modified example is described hereafter focusing on the differences from this embodiment.

In the first modified example, the first pipe connection assembly 600-1 is characterized by having a first expansion pipe 620. The first expansion pipe 620 can be provided when the inner diameters of the first through-hole 518a and the upper branch line 534 that is a process fluid supply line are different from each other. In this modified example, the first through-hole 518a has an inner diameter larger than that the upper branch line 534 that is a process fluid supply pipe. The first expansion pipe 620 has a conical shape with a first end portion 622, a second end portion 624, and a tapered portion 626. The first end portion 622 of the first expansion pipe 620 has a first inner diameter the same as the inner diameter of the first protruding port 610. The second end portion 624 has a second inner diameter the same as the inner diameter of the first connection pipe 630. The tapered portion 626 connects the first end portion 622 and the second end portion 624. The inner diameter of the first protruding port 610 may be the same as that of the first through-hole 518a and the inner diameter of the first connection pipe 630 may be the same as that of the upper branch line 534 that is a process fluid supply pipe.

The first connection pipe 630 is connected to the first expansion pipe 620 by welding. As an example, the first expansion pipe 620 and the first connection pipe 630 may be welded by butt welding. The first connection pipe 630 has a joint 640 at the upper end for fitting with the upper branch line 534.

The protective cap 650 can be provided to surround the weld between the first protruding port 610 and the first expansion pipe 620 and the weld between the first expansion pipe 620 and the first connection pipe 630. The first protective cap 650 may be composed of two bodies for easy assembly. The first protective cap 650 can be fixed by a separate clamp 660. The clamp 660 can be implemented in various ways.

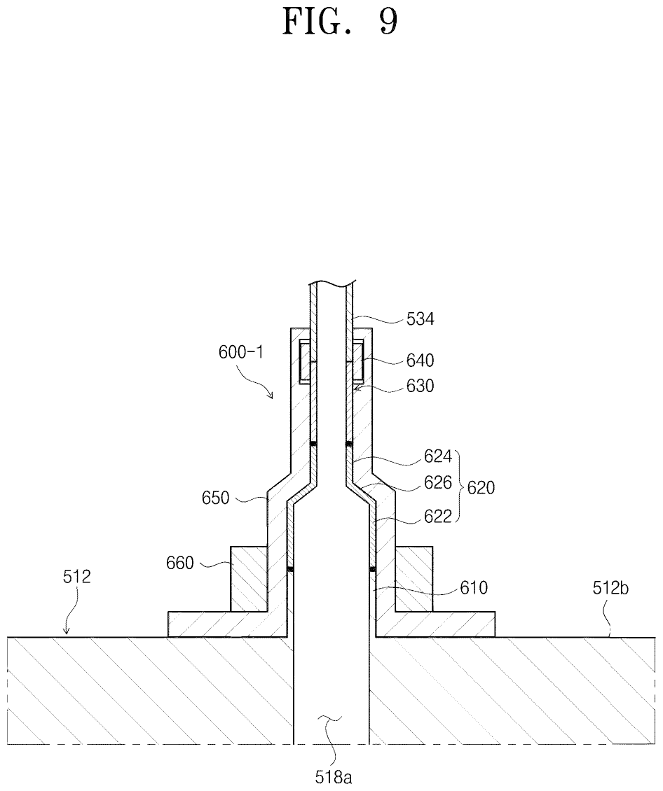

As another example, the first protective cap 650 may be provided even the fitting (joint) portion between the first connection pipe 630 and the upper branch line 534 (see FIG. 9).

Meanwhile, it is preferable that the first through-hole 518a, the first protruding port 610, the first expansion pipe 620, and the first connection pipe 630 has roughness the same as the surface roughness of the inner surface of the upper branch line 534. Since the first through-hole 518a, the first protruding port 610, the first expansion pipe 620, and the first connection pipe 630 has roughness the same as the surface roughness of the inner surface of the upper branch line 534, it is possible to prevent a pressure drop loss and turbulence generation and minimize contamination in the treatment space. The surface treatment of the first through-hole 518a was described above, so it is not described.

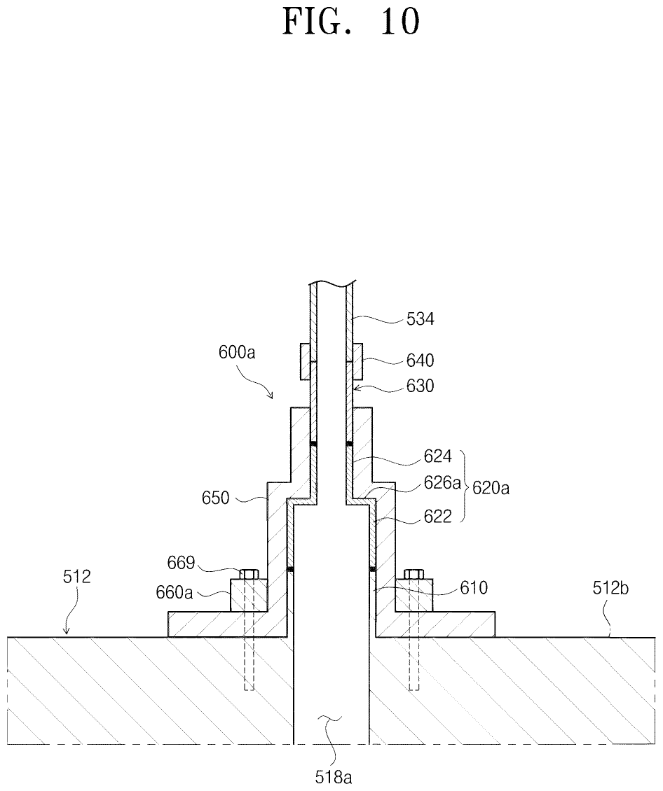

FIG. 10 is a view showing another example of a first expansion pipe of the first pipe connection assembly shown in FIG. 7.

As shown in FIG. 10, a first expansion pipe 620a has a first end portion 622, a second end portion 624, and a connecting portion 626a. The first end portion 622 of the expansion pipe 620 has a first inner diameter the same as the inner diameter of the protruding port 610. The second end portion 624 has a second inner diameter the same as the inner diameter of the first connection pipe 630. The connecting portion 626 is connected to the first end portion 622 and the second end portion 624 at a right angle.

Meanwhile, the clamp 660a fixing the first protective cap 650 can be fixed to the upper body by a bolt 669.

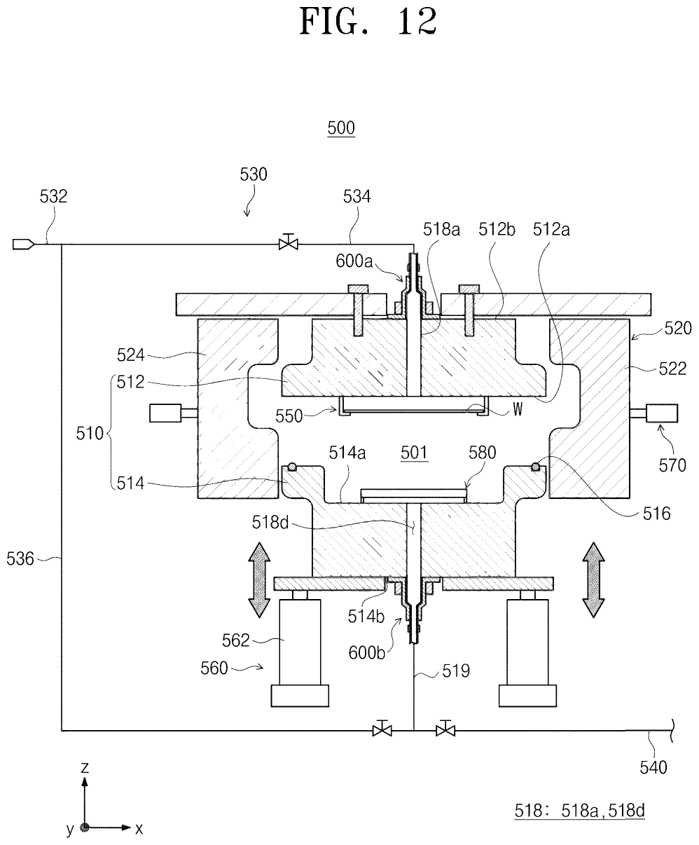

FIG. 12 is a view schematically showing a modified example of a drying chamber.

Referring to FIG. 12, the drying chamber includes a chamber body 510, a clamping body 520, a fluid supply unit 530, a fluid exhaust line 540, a supporting member 550, a first moving unit 560, a second moving unit 570, and a filler member 600, and these are similar in configuration and function to the chamber body 510, the clamping body 520, the fluid supply unit 530, the fluid exhaust line 540, the supporting member 550, the first moving unit 560, the second moving unit 570, and the filler member 600 shown in FIG. 3, so the modified example is described hereafter focusing on the differences from this embodiment.

According to the modified example, one common through-hole 518d may be provided in the lower body 514. The common through-hole 518d can be used as a supply passage through which a process fluid is supplied to the treatment space 501 and can be used as an exhaust passage through which the fluid in the treatment space 501 is exhausted. The common through-hole 518d may be provided at the center of the lower wall of the lower body 514. The center of the lower wall may be a position corresponding to the center of a substrate W on a vertical line when a substrate W is supported on the supporting member 550.

A common line 519 is connected to the common through-hole 518d, and the lower branch line 536 of the fluid supply line 530 and the fluid exhaust line 540 may be connected to the common line 519. While a process fluid is supplied to the treatment space 501, the valve of the fluid exhaust line 540 is closed, and while the fluid in the treatment space 501 is discharged, the valve of the lower branch line 536 is closed.

The common line 519 is connected to the common through-hole 518d through a second pipe connection assembly 600b. In this modified example, the first pipe connection assembly 600b and the second pipe connection assembly 600b are shown identically to the pipe connection assemblies shown in FIG. 7, but they are not limited thereto and various pipe connection assemblies disclosed in the present invention can be applied.

The specification provides examples of the present invention. Further, the description provides an embodiment of the present invention and the present invention may be used in other various combination, changes, and environments. That is, the present invention may be changed or modified within the scope of the present invention described herein, a range equivalent to the description, and/or within the knowledge or technology in the related art. The embodiment shows an optimum state for achieving the spirit of the present invention and may be changed in various ways for the detailed application fields and use of the present invention. Therefore, the detailed description of the present invention is not intended to limit the present invention in the embodiment. Further, the claims should be construed as including other embodiments.

What is claimed is:

1. A substrate treating apparatus comprising:
a vessel providing a sealable treatment space; and
a substrate supporting member positioned in the treatment space of the vessel and supporting a substrate,
wherein the vessel comprises:
a through-hole formed through from an outer surface to an inner surface such that a process fluid is supplied to the treatment space; and
a pipe connection assembly provided on an outer surface on which the through-hole is formed, and provided for connection with a process fluid supply pipe.

2. The substrate treating apparatus of claim 1, wherein the pipe connection assembly comprises:
a protruding port through which the through-hole extends and that protrudes from the outer surface; and
a connection pipe connected to the protruding port by welding and having a joint for fitting with the process fluid supply pipe.

3. The substrate treating apparatus of claim 2, wherein the pipe connection assembly further comprises:
an expansion pipe provided between the protruding port and the connection pipe when diameters of the through-hole and the process fluid supply pipe are different; and
a protective cap provided to surround a weld between the protruding port and the expansion pipe and a weld between the expansion pipe and the connection pipe, and
the expansion pipe is connected to the protruding port and the connection pipe by welding.

4. The substrate treating apparatus of claim 3, wherein the protective cap is provided to surround the joint.

5. The substrate treating apparatus of claim 3, wherein the expansion pipe has a first end portion having a first inner diameter the same as an inner diameter of the protruding port, a second end portion having a second inner diameter the same as an inner diameter of the connection pipe, and a connecting portion connecting the first end portion and the second end portion;
the inner diameter of the protruding port is the same as an inner diameter of the through-hole; and
the inner diameter of the connecting pipe is the same as an inner diameter of the process fluid supply pipe.

6. The substrate treating apparatus of claim 2, wherein the through-hole has roughness the same as surface roughness of an inner surface of the process fluid supply pipe.

7. The substrate treating apparatus of claim 6, wherein the through-hole is electro-polished.

8. The substrate treating apparatus of claim 5, wherein the through-hole has an inner diameter larger than the inner diameter of the process fluid supply pipe.

9. The substrate treating apparatus of claim 2, wherein the process fluid is a supercritical fluid.

10. A substrate treating apparatus comprising:
a vessel providing a sealable treatment space through a combination of an upper body and a lower body; and
a substrate supporting member positioned in the treatment space of the vessel and supporting a substrate,
wherein the upper body comprises a first through-hole formed through from an inner lower surface in contact with the treatment space to an outer upper surface, and a first pipe connection assembly provided on the outer upper surface for connection of the first through-hole and a first process fluid supply pipe; and
the lower body comprises a second through-hole formed through from an inner top surface being in contact with the treatment space to an outer lower surface, and a second pipe connection assembly provided on the outer lower surface for connection of the second through-hole and a second process fluid supply pipe.

11. The substrate treating apparatus of claim 10, wherein the first pipe connection assembly comprises:
a first protruding port through which the first through-hole extends and that protrudes from the outer upper surface; and
a first connection pipe connected to the first protruding port by welding and having a joint for fitting with the first process fluid supply pipe, and
the second pipe connection assembly comprises:
a second protruding port through which the second through-hole extends and that protrudes from the outer lower surface; and
a second connection pipe connected to the second protruding port by welding and having a joint for fitting with the second process fluid supply pipe.

12. The substrate treating apparatus of claim 11, wherein the first pipe connection assembly further comprises:
a first expansion pipe provided between the first protruding port and the first connection pipe when diameters of the first through-hole and the first process fluid supply pipe are different, and connected to the first protruding port and the first connection pipe by welding; and
a first protective cap provided to surround a weld between the first protruding port and the first expansion pipe and a weld between the first expansion pipe and the first connection pipe, and
the second pipe connection assembly further comprises:
a second expansion pipe provided between the second protruding port and the second connection pipe when diameters of the second through-hole and the second process fluid supply pipe are different, and connected to the second protruding port and the second connection pipe by welding; and
a second protective cap provided to surround a weld between the second protruding port and the second expansion pipe and a weld between the second expansion pipe and the second connection pipe.

13. The substrate treating apparatus of claim 12, wherein the first and second protective caps are provided to surround the joint.

14. The substrate treating apparatus of claim 12, wherein the first expansion pipe and the second expansion pipe have a first end portion having a first inner diameter the same as inner diameters of the first and second protruding ports, a second end portion having a second inner diameter the same as inner diameters of the first and second connection pipes, and a connecting portion connecting the first end portion and the second end portion;
the inner diameters of the first and second protruding ports are the same as inner diameters of the first and second through-holes;
the inner diameters of the first and second connection pipes are the same as inner diameters of the first and second process fluid supply pipes; and
the first and second through-holes have an inner diameter larger than the inner diameters of the first and second process fluid supply pipes.

15. The substrate treating apparatus of claim 11, wherein the first and second through-holes have roughness the same as surface roughness of inner surfaces of the first and second process fluid supply pipes.

16. The substrate treating apparatus of claim 11, wherein the first and second through-holes are electro-polished.

17. The substrate treating apparatus of claim 11, wherein the process fluid is a supercritical fluid.

18. A substrate treating apparatus comprising:
a vessel providing a sealable treatment space through a combination of an upper body and a lower body; and
a substrate supporting member positioned in the treatment space of the vessel and supporting a substrate,
wherein the upper body and the lower body each comprise:
a through-hole formed through from an outer surface to an inner surface such that a process fluid is supplied to the treatment space; and
a pipe connection assembly provided on an outer surface on which the through-hole is formed, and provided for connection with a process fluid supply pipe, and
the pipe connection assembly comprises:
a protruding port through which the through-hole extends and that protrudes from the outer surface;
an expansion pipe connected to the protruding port by welding; and
a connection pipe connected to the expansion pipe by welding and having a joint for fitting with the process fluid supply pipe.

19. The substrate treating apparatus of claim 18, wherein the pipe connection assembly further comprises a protective cap provided to surround a weld between the protruding port and the expansion pipe and a weld between the expansion pipe and the connection pipe.

20. The substrate treating apparatus of claim 19, wherein the expansion pipe has a first end portion having a first inner diameter the same as an inner diameter of the protruding port, a second end portion having a second inner diameter the same as an inner diameter of the connection pipe, and a connecting portion connecting the first end portion and the second end portion;
the inner diameter of the protruding port is the same as an inner diameter of the through-hole;
the inner diameter of the connection pipe is the same as an inner diameter of the process fluid supply pipe;
the first and second through-holes have an inner diameter larger than inner diameters of the first and second process fluid supply pipes; and
the through-hole has roughness the same as surface roughness of an inner surface of the process fluid supply pipe.
